(19) United States
(12) Patent Application Publication
(10) Pub. No.: US 2011/0151118 A1
(43) Pub. Date: Jun. 23, 2011

(54) TREATMENT SYSTEM USING A FLUID CAPABLE OF PHASE CHANGE

(75) Inventors: David Kazemi, Lee's Summit, MO (US); Martin G. Hatfield, Odessa, MO (US)

(73) Assignee: General Electric Company

(21) Appl. No.: 12/643,080

(22) Filed: Dec. 21, 2009

(51) Int. Cl. B05D 5/00; C23C 16/00

(52) U.S. Cl. 427/243; 118/715

(57) ABSTRACT

An apparatus and a system and method for treating a material are provided. The apparatus includes a vessel that includes a perforated core disposed within the vessel and a dip tube disposed within the core. The dip tube is in fluid communication with the treatment vessel at a first port and has at least one opening that is located within a non-perforated region of the perforated core and distal from the first port. The system includes a vessel that includes a perforated core disposed within the vessel and a dip tube disposed within the core. The dip tube is in fluid communication with the treatment vessel at a first port and has at least one opening that is located within a non-perforated region of the perforated core and distal from the first port. The system also includes at least one solution supply that comprises a solvent capable of changing phase in response to a change in temperature and/or pressure.

### BACKGROUND OF THE INVENTION

This invention relates generally to a treatment system and method for treating a material. In particular, the invention relates to a system and method for treating a porous sheet material with a fluid capable of phase change.

Pressurized treatment vessels are used to modify one or more property of a material such as, for instance, a porous sheet material such as a membrane. One known treatment vessel has a perforated core upon which the porous sheet material is disposed. During the treatment process a treatment solution is used to deposit or otherwise incorporate a treatment substance into the porous sheet material as it circulates through the treatment vessel.

During discharge of the solution, the solvent is prone to changing phase and causing imperfections in the treated porous sheet material. For instance, if the solvent changes from either a gas or liquid to a solid such as ice or dry ice, the solid solvent may deposit on the porous sheet material and cause marks or other imperfections that render the sheet material less than completely treated and may also clog lines in the system.

### BRIEF DESCRIPTION OF THE INVENTION

An apparatus and a system for treating a material are described herein. One aspect of the invention is an apparatus. The apparatus comprises a vessel and the vessel has first and second ports for fluid communication with the exterior of the vessel. The apparatus further comprises a perforated core. The perforated core has at least one non-perforated region at an end portion of the perforated core. The perforated core is adapted to be disposed within the vessel so the interior of the perforated core is in fluid communication with the first port and the exterior of the perforated core is in fluid communication with the second port. The perforated core is further adapted to be disposed so the non-perforated region is located distal from the first port. The apparatus further comprises a dip tube. The dip tube has at least one opening in an end portion. The dip tube is adapted to be disposed within the perforated core and is in fluid communication with the first port. The dip tube is adapted to be disposed so the opening in the end portion is located within the non-perforated region of the perforated core.

Another aspect of the invention is a system for treating a material. The system comprises at least one solution supply. The solution comprises a solvent capable of changing phase in response to a change in at least one of a pressure and temperature. The system further includes a vessel having first and second ports for fluid communication with the exterior of the vessel. The system further comprises a perforated core. The perforated core has at least one non-perforated region at an end portion of the perforated core. The perforated core is adapted to be disposed within the vessel so the interior of the perforated core is in fluid communication with the first port and the exterior of the perforated core is in fluid communication with the second port. The perforated core is further adapted to be disposed so the non-perforated region is located distal from the first port. The system further comprises a dip tube. The dip tube has at least one opening in an end portion. The dip tube is adapted to be disposed within the perforated core and is in fluid communication with the first port. The dip tube is adapted to be disposed so the opening in the end portion is located within the non-perforated region of the perforated core.

Another aspect of the invention is a method of treating porous sheet material in a vessel with fluid capable of changing phase in response to a change in at least one of a pressure and temperature within the vessel. The method comprises a step of providing a perforated core for receiving the porous sheet material. The perforated core has at least one non-perforated region at an end portion of the perforated core. The perforated core is adapted to be disposed so the non-perforated region is located distal from the first port. The method further comprises the step of providing a dip tube having at least one opening in an end portion. The dip tube is adapted to be disposed within the perforated core. The dip tube is further adapted to be disposed so the opening in the end portion is located within the non-perforated region of the perforated core. The method further comprises the step of exhausting fluid from the vessel to change phase of the fluid. The method further comprises the step of extracting fluid from the non-perforated region of the perforated core through the dip tube.

### BRIEF DESCRIPTION OF THE DRAWINGS

These and other features, aspects, and advantages of the invention will be better understood when the following detailed description is read with reference to the accompanying drawings, in which:

FIG. 1 is a schematic view of one embodiment of the system of the present invention;

FIG. 2 is a schematic view of one embodiment of the system of the present invention; and

FIG. 3 is an enlarged, cross sectional view of the end portion of the dip tube of the present invention during the discharge process.

### DETAILED DESCRIPTION OF THE INVENTION

One aspect of the present invention includes an apparatus and a system for treating a porous sheet material to change or modify one or more of its properties or characteristics. The porous sheet material is disposed on a perforated core and is treated in a vessel with a solution comprising at least one solvent capable of changing phase in response to a change in temperature and/or pressure. The solution may further comprise a treatment material that is dissolved in the solvent, however, the use of a treatment material or other solute is not required. Therefore, as described herein, the term “solution” may include pure solvent as well as solvent that contains a dissolved solute, such as a treatment material. One suitable solvent may be CO₂.

After treatment, as solution is discharged from the vessel, the resultant change in temperature and/or pressure causes the solvent to change phase and the resulting fluid to build up in the interior of the perforated core of the treatment vessel. This buildup is removed from the interior of the core before it can cause imperfections in the porous sheet material. The system is especially well suited to treating open pore membranes, such as expanded polytetrafluoroethylene (ePTFE) membranes, with treatment materials dissolved in carbon dioxide in a supercritical state (SCCO₂).

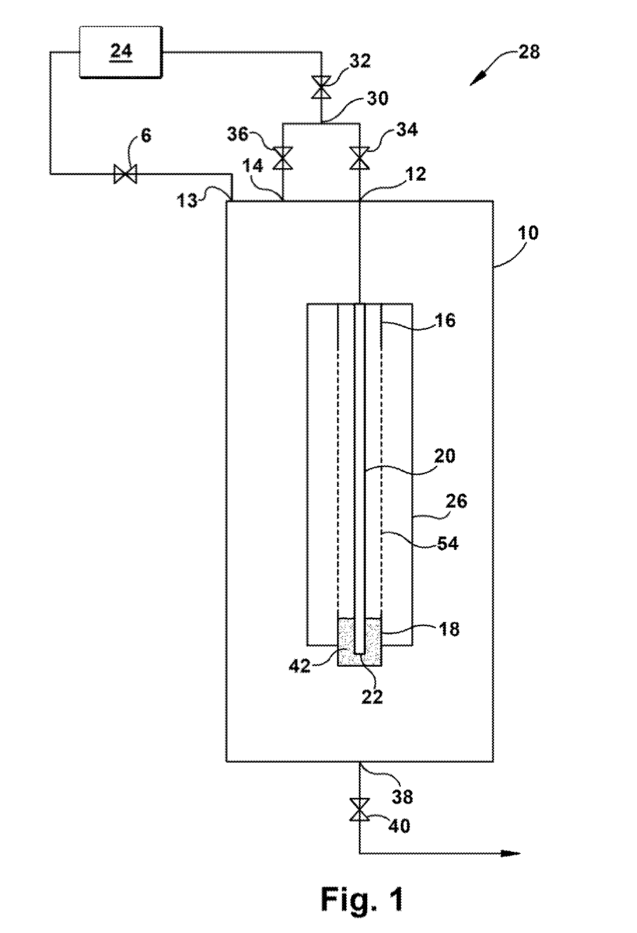

One embodiment of the system of the present invention is shown in FIG. 1. The system 28 includes at least one solution supply 24. The solution comprises at least one solvent capable of changing phase in response to a change in at least one of a pressure and temperature. The solution is fed to a treatment vessel 10. The treatment vessel 10 has a perforated core 16 that is adapted to be disposed within the vessel 10 such that the interior of the perforated core 16 is in fluid communication with a first port 12 and the exterior of the perforated core 16 is in fluid communication with a second port 14.

The perforated core 16 has at least one non-perforated region 18 that is at an end portion of the perforated core 16. The non-perforated region 18 is located distal from the first port 12. A dip tube 20 having at least one opening 22 in an end portion is disposed within the perforated core 16. The dip tube 20 is in fluid communication with the first port 12 and is adapted to be disposed so the opening 22 in the end portion is located within the non-perforated region 18 of the perforated core 16.

Material to be treated such as, for instance, a porous sheet material 26, may be disposed on the perforated core 16. In one embodiment, as shown in FIG. 1, the porous sheet material 26 is wound around the perforated core 16 in roll form.

The porous sheet material 26 is treated by charging the treatment vessel 10 with solution from the solution supply 24, through a third port 30. When using the configuration shown in the embodiment of FIG. 1, the third port 30 is in fluid communication with both the first port 12 and the second port 14, and the solution supply 24 feeds the treatment vessel 10 by way of both the first port 12 and second port 14. As solution enters the treatment vessel 10 through the first port 12 it flows through the opening 22 of the dip tube 20, into the interior region of the perforated core 16 and then permeates the porous sheet material 26. At the same time solution enters the treatment vessel 10 through the second port 14 and diffuses through the porous sheet material 26 towards the perforated core 16. In this way the solution may efficiently and thoroughly permeate the porous sheet material 26 from both sides of the wound roll.

After the treatment vessel 10 has been charged with solution, penetration through the porous sheet material 26 may optionally be enhanced by circulating the solution. Referring to FIG. 1, this can be accomplished by pumping the solution from the solution supply 24 through the first port 12 into the interior of the perforated core 16. The solution flows axially outward through the perforated core 16, through the porous sheet material 26, and into the treatment vessel 10. The circulation loop is completed by allowing the solution to exit the treatment vessel 10 through a fourth port 13 to return to the solution supply 24. This circulation can be accomplished by opening the first port valve 34, the third port valve 32, and the fourth port valve 6 while closing the second port valve 36 and the fifth port valve 40. In this way the solution will flow from inside to outside with respect to the perforated core 16. In an alternative aspect of the invention the solution is circulated from the treatment vessel 10 axially inward toward the interior of the perforated core 16. This is accomplished by reversing the direction of flow using the same valve alignment described above and pumping in the reverse direction.

As shown in FIG. 1, in one embodiment the third port 30 is in fluid communication with both the first port 12 and second port 14 and thus solution may be fed to the treatment vessel 10 by way of the first port 12 and second port 14. However, this is not required, as the solution may be introduced into the vessel 10 using one or more separate ports (not shown).

After the solution has been thoroughly circulated throughout the treatment vessel 10 the solution is discharged through a fifth port 38 by opening a fifth port valve 40. During this discharge step the temperature and/or pressure inside the vessel 10 typically changes and causes the solution and/or solvent to change phase and deposit precipitated material onto the surfaces defining the pores of the porous sheet material 26. This phase change can cause solution buildup 42 in the interior of the non-perforated region 18 of the perforated core 16. The solution buildup 42 is primarily a fluid, and may be comprised of solution, solvent, treatment substance, or a combination of these.

During discharge, the solution buildup 42 is extracted from the non-perforated region 18 of the perforated core 16 via differential pressure by flowing into the opening 22 in the dip tube 20, and through the first port 12. In the embodiment shown in FIG. 1 the solution buildup 42 then flows through the second port 14, and then into the treatment vessel 10 where it may finally be discharged from the treatment vessel 10 through the fifth port 38.

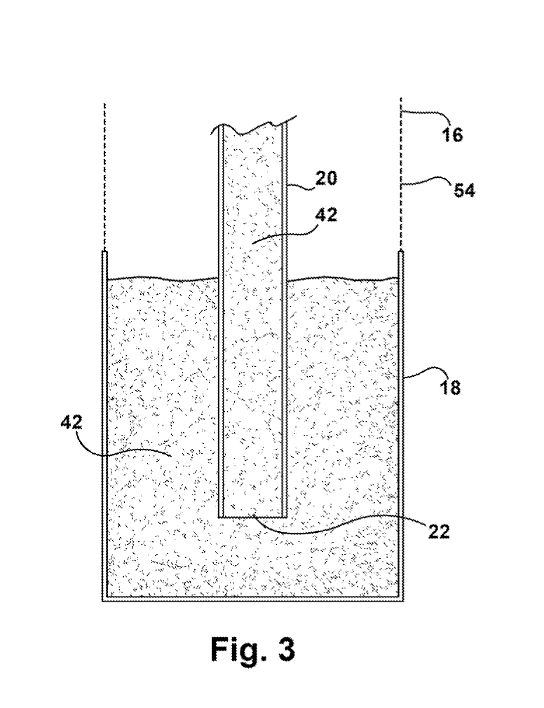

If the solution buildup 42 remains in the perforated core 16 it can rise to a level above the non-perforated region 18 of the perforated core 16, and can contact the porous sheet material 26 through the perforations 54 in the perforated core 16. This contact can cause imperfections. An advantage that may be realized in the practice of some embodiments of the described system 28 and techniques is the extraction of the solution buildup 42 so that it does not flow through the perforations 54 in the perforated core 16 and contact the porous sheet material 26. A further advantage that may be realized in the practice of some embodiments of the described system 28 and techniques is the rapid extraction of the solution buildup 42 while it is a fluid, enabling its removal from the vessel 10 before it turns into a solid as the temperature and/or pressure in the vessel 10 change during the discharge process. FIG. 3 shows and enlarged cross-sectional view of the non-perforated region 18 at the end portion of the perforated core 16, having the opening 22 in the dip tube 20 disposed therein. As shown in this view, during the discharge process, the solution buildup 42 is extracted through the opening 22 in the dip tube 20 so that it may be removed from the interior of the perforated core 16.

By way of example, if the solvent is carbon dioxide in a supercritical state (SCCO₂) the solution buildup 42 is comprised primarily of liquid CO₂. The presence of the dip tube 20 enables the liquid CO₂ to be removed from the non-perforated region 18 of the perforated core 16 at a rate sufficient to prevent the liquid CO₂ from rising to a level above the non-perforated region 18 of the perforated core 16. This prevents the liquid CO₂ from flowing through the perforations 54 in the perforated core 16 and contacting the adjacent porous sheet material 26. This, in turn, prevents the formation of dry ice on the porous sheet material 26. In addition, the presence of the dip tube 20 enables the liquid CO₂ to be removed from the system 28 quickly so that it does not substantially solidify into dry ice during the discharge process. Since dry ice deposits on porous sheet material 26 can cause imperfections in the porous sheet material 26, this improvement is desirable. In one embodiment, the porous sheet material 26 is an expanded polytetrafluoroethylene (ePTFE) membrane, and the extraction of the liquid CO₂ via the dip tube 20 prevents the formation of dry ice (solid CO₂) on the ePTFE membrane.

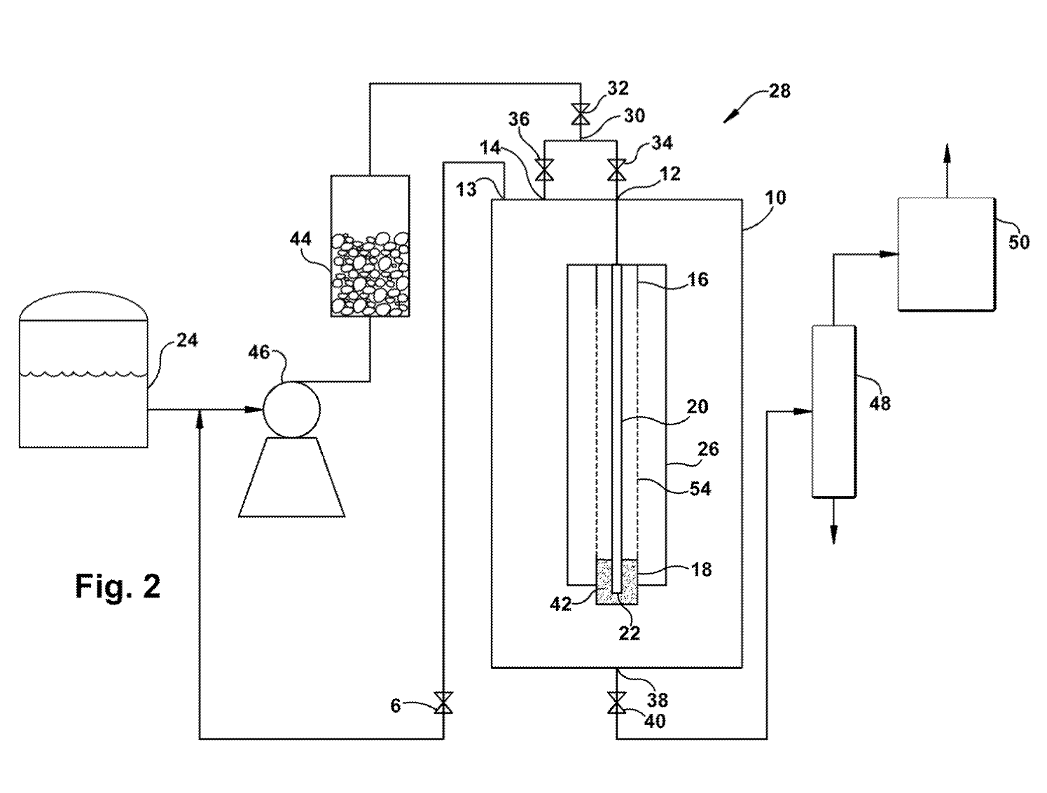

In one embodiment, the first port 12 and second port 14 are in fluid communication with one another as shown in FIGS. 1 and 2. This can aid in pressure equalization between the interior and exterior regions of the perforated core 16 during charging, circulation, and/or discharge. However, in an alternative embodiment (not shown) the first and second ports are not in fluid communication with one another.

As shown in FIG. 2, the system 28 of the present invention may optionally include additional components as deemed suitable by the practitioner. In various embodiments, the system 28 may include any or all of the following components: a pump 46 for charging the treatment vessel 10 with solution, a cyclone 48 for recovery of solid treatment material from discharged solution, and a bag house 50 or other filtration mechanism for fine particulate capture from solvent that is vented to the atmosphere.

The solution may comprise either only solvent, or solvent having one or more treatment substances dissolved therein. If a treatment substance is used it is substantially dissolved in the solvent prior to entering the treatment vessel 10. In one embodiment, as shown in FIG. 2, the treatment substance is combined with the solvent via a dissolver 44 prior to entering the treatment vessel 10.

The solvent may be any suitable to effect or facilitate the treatment of the material, including, but not limited to, SCCO₂, water, ethanol, isopropyl alcohol (IPA), acetone, methanol, n-propanol, n-butanol, N—N-dimethylformamide, methyl ethyl ketone, and water soluble and e- and p-series glycol ethers. The solvent is capable of changing state in response to either a change in temperature, a change in pressure, or a change in both temperature and pressure.

Treatment may be required to change or modify one or more property or characteristic of a porous sheet material 26. The treatment substance may be any that will change at least one property or characteristic of the material, such as, without limitation, color, oleophobicity, hydrophilicity, electrical conductivity, optical reflectivity, ion conductivity, or porosity. Examples of suitable treatment substances include, without limitation, polyvinyl nucleophilic polymer, blocked isocyanate, a dispersion of organofunctional siloxane solids such as dispersions of ECM/D6455 Hydrophilic Coating in Acetone, available from Whitford Corporation of Frazer, Pennsylvania, and/or ECM/D6453 Hydrophilic Coating, IPA, also available from Whitford Corporation, polyether urethane polymer solids such as Permax® 200, available from Noveon, Inc. of Cleveland, Ohio, a urethane or fluorinated urethane polymer or a polymer containing fluorine such as a fluoroacrylate or fluoromethacrylate polymer such as perfluoro alkyl acrylic copolymer and/or perfluoro alkyl methacrylic copolymer such as water-based dispersions of Zonyl® 8195, 7040, 8412, and/or 8300, available from Dupont of Wilmington, Del.

During charging, cycling, and discharge, the treatment substance may deposit upon, or otherwise interact with, the porous sheet material 26. Thus, the composition of the solution may change as the system 28 is charged, cycled, and discharged.

The system 28 of the present invention is particularly suited to treat a porous sheet material 26. By way of example the porous sheet material 26 may be an open pore membrane. More particularly the system 28 may be used to treat a microporous open pore membrane such as an expanded polytetrafluoroethylene (ePTFE) membrane. The ePTFE membrane is preferably made by extruding a mixture of polytetrafluoroethylene (PTFE) fine powder particles (available from DuPont under the name TEFLON® fine powder resin) and lubricant. The extrudate is then calendared. The calendared extrudate is then “expanded” or stretched in at least one and preferably two directions to form the fibrils connecting the nodes in a three-dimensional matrix or lattice type of structure. “Expanded” is intended to mean sufficiently stretched beyond the elastic limit of the material to introduce permanent set or elongation to the fibrils. The membrane is preferably then heated or “sintered” to reduce and minimize residual stress in the membrane material. However, the membrane may be unsintered or partially sintered as is appropriate for the contemplated use of the membrane.

Other suitable materials and methods can be used to form a suitable porous sheet material 26. For example, other suitable materials that may be used to form a porous sheet material 26 include polyolefin, polyamide, polyester, polysulfone, polyether, acrylic and methacrylic polymers, polystyrene, polyurethane, polypropylene, polyethylene, cellulosic polymer and combinations thereof. Other suitable methods of making a porous sheet material 26 include foaming, skiving, or casting any of the suitable materials.

In one aspect of the invention the porous sheet material 26 is a laminate of multiple porous sheet materials. For example, the porous sheet material 26 may comprise an ePTFE membrane laminated to another open pore material such as a porous textile substrate. Nonlimiting examples of suitable porous textile substrates include woven or nonwoven fabrics made from nylon, polyester, or polypropylene.

There are numerous uses for a porous sheet material 26 that has a property or characteristic changed or modified. By way of example, a laminated fabric incorporating a treated or modified porous sheet material 26, made according to the present invention, may be used in garments or apparel.

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal languages of the claims.

What is claimed is:

1. An apparatus comprising:
a vessel having first and second ports for fluid communication with the exterior of the vessel;
a perforated core having at least one non-perforated region at an end portion of the perforated core, the perforated core adapted to be disposed within the vessel so the interior of the perforated core is in fluid communication with the first port and the exterior of the perforated core is in fluid communication with the second port, the perforated core adapted to be disposed so the non-perforated region is located distal from the first port; and
a dip tube having at least one opening in an end portion, the dip tube adapted to be disposed within the perforated core and in fluid communication with the first port, the dip tube adapted to be disposed so the opening in the end portion is located within the non-perforated region of the perforated core.

2. The apparatus of claim 1, wherein the vessel is substantially cylindrical and vertically oriented.

3. The apparatus of claim 1, wherein the perforated core and the tube are concentrically arranged along the central axis of the vessel.

4. A system for treating a material, the system comprising:
at least one solution supply, the solution comprising a solvent capable of changing phase in response to a change in at least one of a pressure and temperature;
a vessel having first and second ports for fluid communication with the exterior of the vessel;
a perforated core having at least one non-perforated region at an end portion of the perforated core, the perforated core adapted to be disposed within the vessel so the interior of the perforated core is in fluid communication with the first port and the exterior of the perforated core is in fluid communication with the second port, the perforated core adapted to be disposed so the non-perforated region is located distal from the first port; and
a dip tube having at least one opening in an end portion, the dip tube adapted to be disposed within the perforated core and in fluid communication with the first port, the dip tube adapted to be disposed so the opening in the end portion is located within the non-perforated region of the perforated core.

5. The system of claim 4, wherein the vessel is substantially cylindrical and vertically oriented.

6. The system of claim 4, wherein the perforated core and the tube are concentrically arranged along the central axis of the vessel.

7. The system of claim 4, the solution further comprising at least one treatment substance for applying to the material, the treatment substance soluble in the solvent at a predetermined temperature and pressure.

8. The system of claim 4, wherein the material is a porous sheet material that is wound on the core.

9. The system of claim 4, wherein the solvent is a fluid at supercritical conditions.

10. The system of claim 9, wherein the fluid is carbon dioxide.

11. The system of claim 8, wherein the porous sheet material comprises an open pore membrane.

12. The system of claim 11, wherein the open pore membrane is expanded polytetrafluoroethylene (ePTFE) membrane.

13. The system of claim 8, wherein the porous sheet material is being treated to modify at least one property selected from the group consisting of oleophobicity, hydrophilicity, electrical conductivity, optical reflectivity, ion conductivity, porosity, and color.

14. The system of claim 7, wherein the treatment substance is selected from the group consisting of a fluorinated urethane polymer and a fluoroacrylate polymer.

15. A method of treating porous sheet material in a vessel with fluid capable of changing phase in response to a change in at least one of a pressure and temperature within the vessel, the method comprising the steps of:
providing a perforated core for receiving the porous sheet material, the perforated core having at least one non-perforated region at an end portion of the perforated core, the perforated core adapted to be disposed so the non-perforated region is located distal from the first port;
providing a dip tube having at least one opening in an end portion, the dip tube adapted to be disposed within the perforated core, the dip tube adapted to be disposed so the opening in the end portion is located within the non-perforated region of the perforated core;
exhausting fluid from the vessel to change phase of the fluid; and
extracting fluid from the non-perforated region of the perforated core through the dip tube.

16. The method of claim 15, wherein the fluid is carbon dioxide at supercritical conditions.

17. The method of claim 15, wherein the porous sheet material comprises an open pore membrane.

18. The method of claim 17, wherein the open pore membrane is expanded polytetrafluoroethylene (ePTFE) membrane.

19. The method of claim 15, wherein the porous sheet material is being treated to modify at least one property selected from the group consisting of oleophobicity, hydrophilicity, electrical conductivity, optical reflectivity, ion conductivity, porosity, and color.

20. The method of claim 15, wherein the fluid comprises a treatment substance selected from the group consisting of a fluorinated urethane polymer and a fluoroacrylate polymer.
